(19) United States
(12) Patent Application Publication
(10) Pub. No.: US 2011/0180126 A1
(43) Pub. Date: Jul. 28, 2011

(54) APPARATUS FOR CONVERGING SOLAR RADIATION

(76) Inventor: Jen Yen YEN, Taichung City (TW)

(21) Appl. No.: 12/692,639

(22) Filed: Jan. 24, 2010

(51) Int. Cl. H01L 31/052

(52) U.S. Cl. 136/246

(57) ABSTRACT

An apparatus for converging solar radiation includes a base which has a heating portion disposed thereon. Two supporting stands are oppositely pivotally mounted a top of the base. Two sensing sheets respectively oppositely disposed on two sides of each supporting stand. Each sensing sheet has a first end mounted on the supporting stand and a second end of the sensing sheet has an elastic unit connected thereto. A converging lens is pivotally mounted on the supporting stands. The converging lens is connected to the elastic units such that the converging lens is located above the heating portion. The sensing sheets slightly expanded and stretched when heated such that the elastic units are driven by the heated sensing sheets to pull the converging lens to incline toward the heated sensing sheets for tracking movement of the sun to maximize absorption of solar radiation.

### BACKGROUND OF THE INVENTION

1. Field of the Invention

The present invention relates to solar energy, and more particularly to an apparatus for converging solar radiation for generation of electricity.

2. Description of Related Art

Energy crisis has become an issue of concern in the recent decades, and has consequently led to interest on seeking for an alternate energy source. Solar energy, with its consistency and accessibility, has become a developing emphasis of the alternate energy source. The utilization of solar energy is therefore developed and is widely adapted in various industries. One common mean for utilizing solar energy is to collect solar energy and convert the collected solar energy to electric power.

A conventional solar energy collector comprises an optical condenser and a photovoltaic cell which is mounted substantially parallel to the optical condenser and placed about midway between the optical condenser and a focus of the optical condenser. The optical condenser can increase the effective area of the photovoltaic cell and increase the output power of existing photovoltaic cells.

However, though the effective area and output power of the photovoltaic cell is increased by the application of the optical condenser, a drawback of the conventional solar energy collector is that the optical condenser is fixedly mounted above the photovoltaic cell, therefore the optical condenser can not detect a position of the sun nor track the movement of the sun, and merely receives sunlight from a single direction. When the sun changes its position throughout the day, the optical condenser is unable to follow and track the position of the sun to automatically adjust its position for maximizing the effective area and output power of the photovoltaic cell. Therefore, the conventional solar energy collector is inconvenient to use.

The present invention has arisen to obviate/mitigate the disadvantages of the conventional apparatus for converging solar radiation.

### SUMMARY OF THE INVENTION

The present invention relates to an apparatus for converging solar radiation comprises a base which has a heating portion disposed thereon. The heating portion is a solar panel for absorbing solar radiation. The base has a supporting post which is mounted to a bottom of the base for securing the base to a ground surface. Two supporting stands are oppositely pivotally mounted on a top of the base and extend upwardly from the base. Each supporting stand includes a first lever which is pivotally mounted on the base and a second lever which has one end pivotally connected to the first lever. The other end of the second lever has two sensing sheets respectively oppositely disposed on two sides thereof and transversely extending outward therefrom. Each sensing sheet has a first end mounted to the second lever. A second end of the sensing sheet has an elastic unit connected thereto. The sensing sheets are made of metals which expand in heat and contract in cold. A converging lens is pivotally mounted on the two supporting stands and is connected to the elastic units such that the converging lens is disposed on the base and is located above the heating portion.

When sunlight passes through the converging lens and heats the sensing sheets, the sensing sheets are slightly expanded and stretched such that the elastic units are driven by the heated sensing sheets to pull the converging lens to incline toward the heated sensing sheets, thereby an incline angle of the converging lens relative to the heating portion is adjusted for tracking movement of the sun to maximize absorption of solar radiation.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is an exploded perspective view of the apparatus for converging solar radiation in accordance with the present invention;

FIG. 2 is an assembled perspective view of the apparatus for converging solar radiation in accordance with the present invention;

FIG. 3 is a partially cross-sectional plane view of the apparatus for converging solar radiation in accordance with the present invention;

FIG. 4 is a partially cross-sectional plane view of the apparatus for converging solar radiation in accordance with the present invention, showing two second levers pivoting upward for adjusting a distance of a converging lens relative to a base; and

FIG. 5 is a partially cross-sectional plane view of the apparatus for converging solar radiation in accordance with the present invention in operating state.

### DETAILED DESCRIPTION OF THE INVENTION

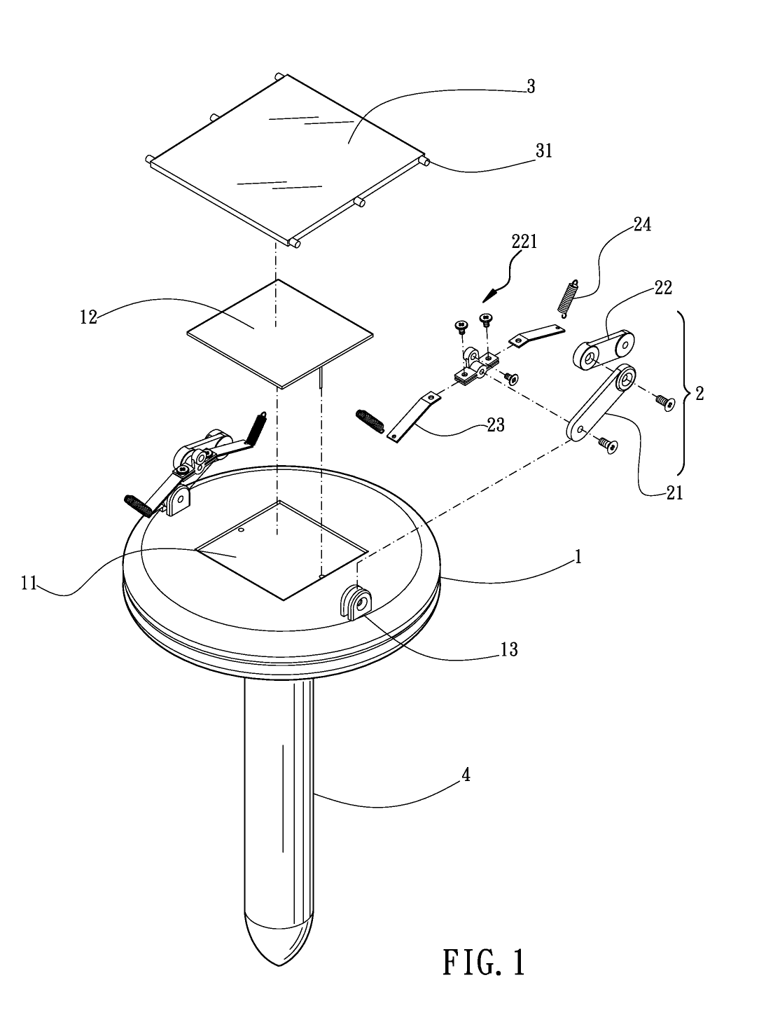

Referring to the drawings and initially to FIGS. 1-3, an apparatus for converging solar radiation in accordance with the present invention comprises a round-shaped base 1 which has a receiving portion 11 defined therein. A heating portion 12 is disposed in the receiving portion 11. The heating portion 12 is a solar panel for absorbing solar radiation. The base 1 has a supporting post 4 which is mounted to a bottom thereof for securing the base 1 to a ground surface. The supporting post 4 has a tapered end such that the supporting post 4 can be easily secured to the ground surface. Two pivotal seats 13 are oppositely disposed on a top of the base 1 and are respectively located corresponding to two sides of the heating portion 12. Two supporting stands 2 are respectively pivotally mounted to the two pivotal seats 13 and extend upwardly from the base 1. Each supporting stand 2 includes a first lever 21 which is pivotally connected to the pivotal seat 13 and a second lever 22 which has one end pivotally connected to the first lever 21. A connecting portion 221 is mounted to the other end of the second lever 22.

Two elongated sensing sheets 23 are respectively oppositely disposed on two sides of the connecting portion 221 and transversely extending outward therefrom. Each sensing sheet 23 has a first end which is screwedly engaged to the connecting portion 221. A second end of the sensing sheet 23 has an elastic unit 24 connected thereto. The sensing sheets 23 are made of metals which expand in heat and contract in cold.

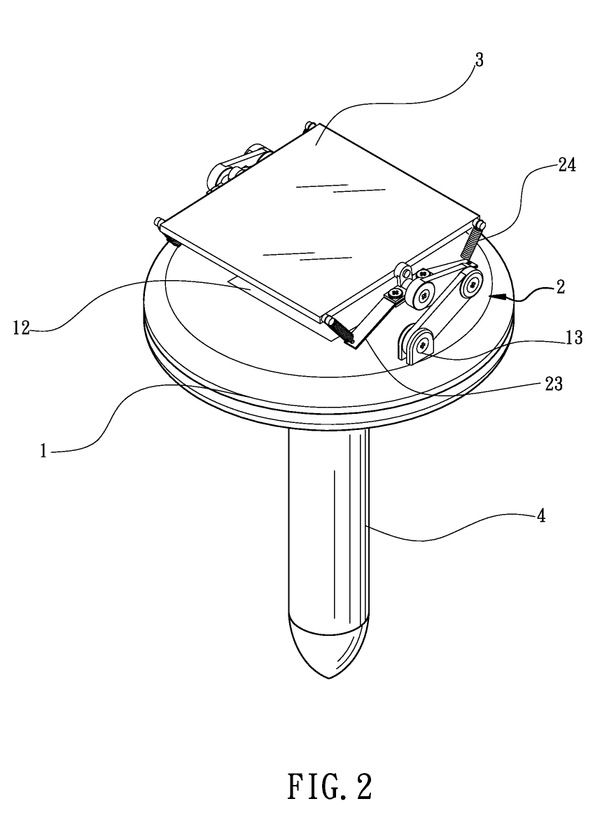

A converging lens 3 is pivotally mounted to the two connecting portions 221. The converging lens 3 has a plurality of ribs 31 protruding from two corresponding lateral sides of the converging lens 3. As shown in FIG. 1 and FIG. 2, in the present embodiment, each of the two lateral sides has three ribs 31 equal-spacedly protruding therefrom. On each lateral side, the rib 31 which is located in the middle among the three ribs 31 is pivotally connected to the connecting portion 221, and the other two ribs 31 are respectively located proximately to corners of the converging lens 3. The four ribs 31 which are located proximately to corners of the converging lens 3 on the two lateral sides are respectively engaged with the elastic units 24 such that the converging lens 3 is suspendedly disposed on the base 1 and is located above the heating portion 12 (FIG. 2). A size of the converging lens 3 is larger than that of the heating portion 12 such that the converging lens 3 is able to collect incoming sunlight from wider angles to effectively increase absorption of the heating portion 12.

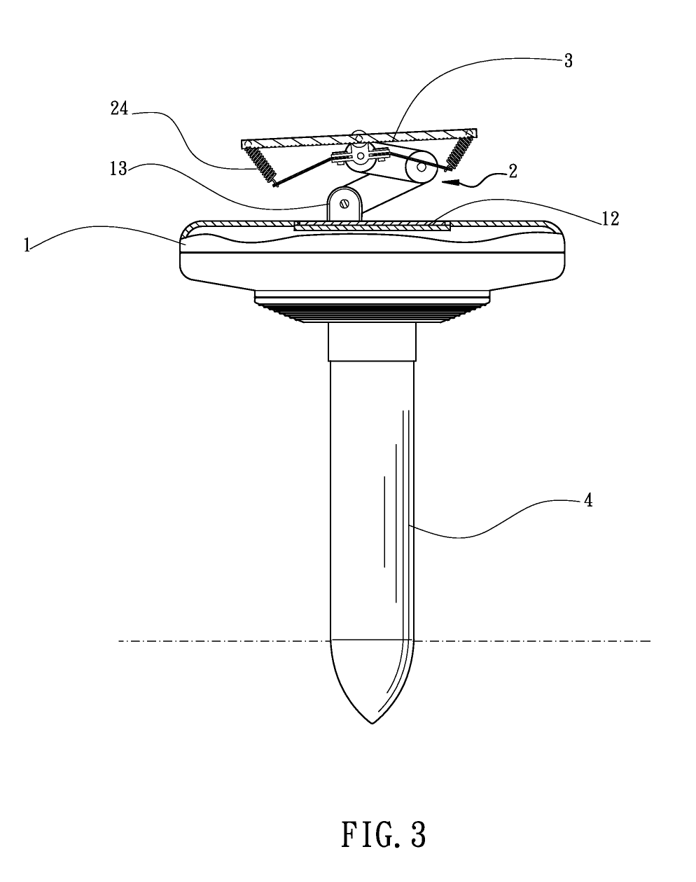

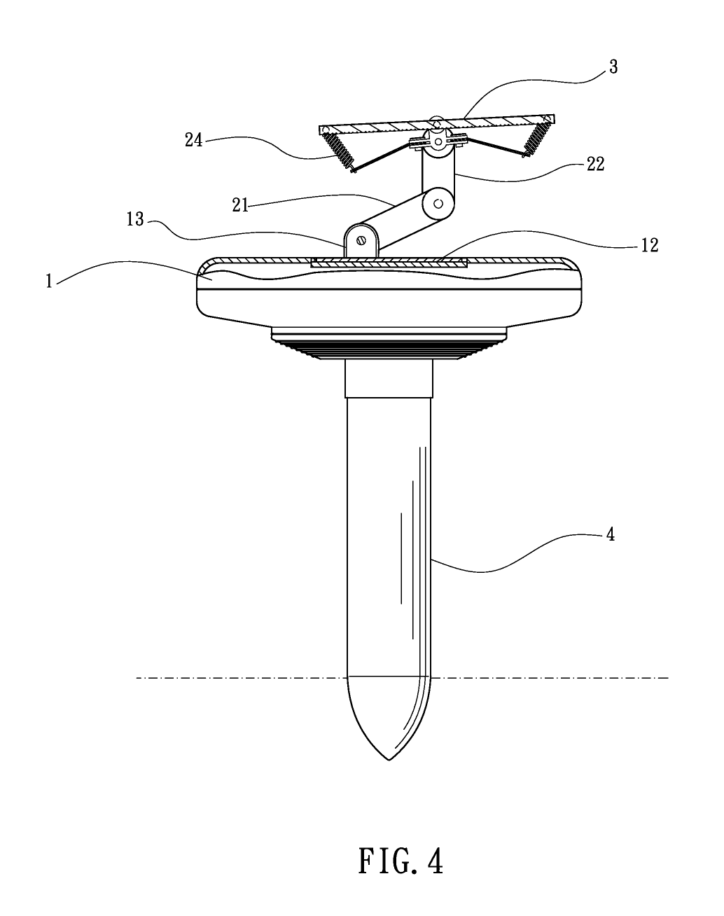

Referring to FIG. 3 and FIG. 4, the first lever 21 is able to pivot relative to the pivotal seat 13, and the second lever 22 is able to pivot relative to the first lever 21, a distance between the converging lens 3 and the heating portion 12 is adjustable by pivoting movements of the first lever 21 and the second lever 22. Therefore, a user is able to manually adjust the converging lens 3 to a desired position by pivoting movements of the first lever 21 and the second lever 22.

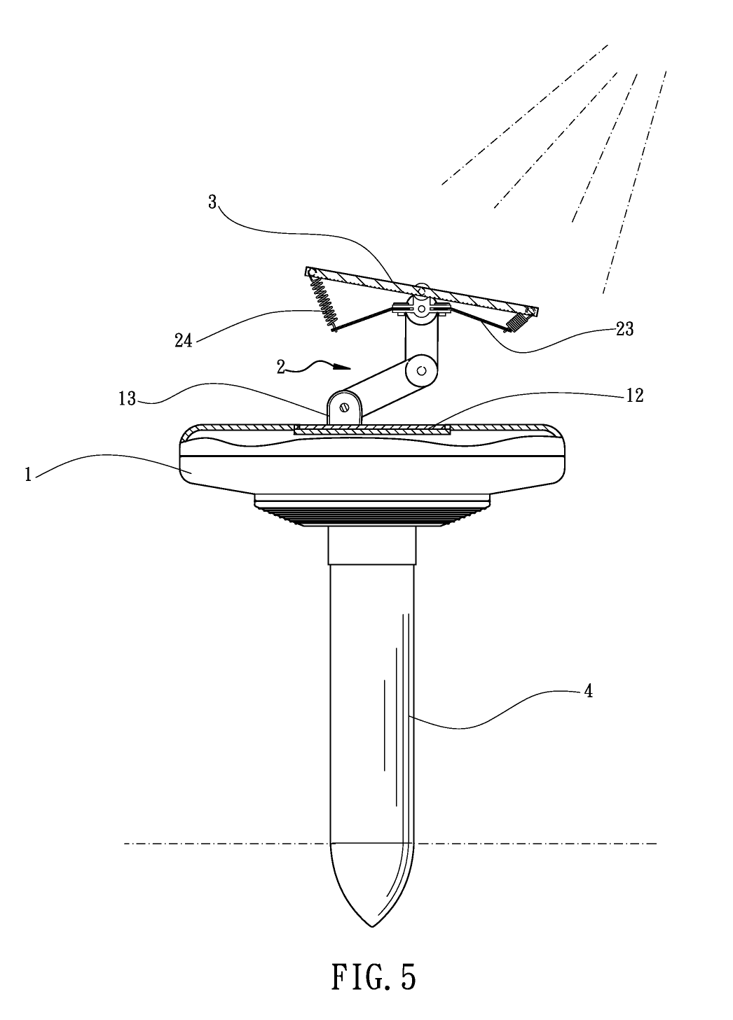

Further referring to FIG. 5, as described above, the sensing sheets 23 expand when in heat and contract in cold, therefore, when sunlight passes through the converging lens 3 and heats the sensing sheets 23, the two sensing sheets 23 which are heated by sunlight are slightly expanded and stretched such that the elastic units 24 connected with the heated sensing sheets 23 are driven to pull the converging lens 3 to incline toward the heated sensing sheets 23; an included angle between the heated sensing sheets 23 and the converging lens 3 is relatively changed, thereby an incline angle of the converging lens 3 relative to the heating portion 12 is adjusted such that the converging lens 3 would continuously incline to face a direction of the sunlight and therefore the converging lens 3 is able to track movement of sun to maximize absorption of solar radiation.

Although the invention has been explained in relations to its preferred embodiment, it is to be understood that many other possible modifications and variations can be made without departing from the spirit and scope of the invention as hereinafter claimed.

What is claimed is:

1. An apparatus for converging solar radiation comprising:
a base, the base having a heating portion disposed thereon for absorbing solar radiation; two supporting stands oppositely pivotally mounted on a top of the base and extending upwardly from the base;
two sensing sheets respectively oppositely disposed on two sides of each supporting stand and extending outward from the supporting stand; each sensing sheet having a first end mounted on the supporting stand, a second end of the sensing sheet having an elastic unit connected thereto; and
a converging lens pivotally mounted on the supporting stands, the converging lens connected to the elastic units such that the converging lens is disposed on the base and is located above the heating portion;
wherein when sunlight passes through the converging lens and heated the sensing sheets, the sensing sheets slightly expanded and stretched such that the elastic units are driven by the heated sensing sheets to pull the converging lens to incline toward the heated sensing sheets, thereby an incline angle of the converging lens relative to the heating portion is adjusted for tracking movement of the sun to maximize absorption of solar radiation.

2. The apparatus for converging solar radiation as claimed in claim 1, wherein each supporting stand includes a first lever pivotally mounted on the base and a second lever having one end pivotally connected to the first lever and the other end connected to the two sensing sheets.

3. The apparatus for converging solar radiation as claimed in claim 1, wherein the base has a supporting post mounted to a bottom thereof for securing the base to a ground surface.

4. The apparatus for converging solar radiation as claimed in claim 1, wherein the heating portion is a solar panel for absorbing solar radiation converged by the converging lens.

5. The apparatus for converging solar radiation as claimed in claim 1, wherein the sensing sheets are made of metals such that the sensing sheets expand in heat and contract in cold.
